(19) United States
(12) Patent Application Publication
(10) Pub. No.: US 2026/0211438 A1
(43) Pub. Date: Jul. 23, 2026

(54) VOLTAGE/CURRENT CONVERSION DEVICE AND CURRENT SOURCE DEVICE

(71) Applicant: THINE ELECTRONICS, INC., Tokyo (JP)

(72) Inventors: Hideyuki KOKATSU, Tokyo (JP); Yusuke FUJITA, Tokyo (JP)

(73) Assignee: THINE ELECTRONICS, INC., Tokyo (JP)

(21) Appl. No.: 19/139,953

(22) PCT Filed: Nov. 9, 2023
(86) PCT No.: PCT/JP2023/040479

§ 371 Date: Jun. 17, 2025

(30) Foreign Application Priority Data
Dec. 22, 2022 (JP) 2022-205478

(51) Int. Cl. G05F 1/575; G05F 1/56; H01S 5/042; H03F 3/45

(52) U.S. Cl. CPC G05F 1/575; G05F 1/561; H01S 5/042; H03F 3/45282

(57) ABSTRACT

The voltage-current conversion device 1A includes a current supply circuit 10A, a differential circuit 20A, a voltage booster 30, and a controller 40A. The current supply circuit 10A includes a first NMOS transistor 11, a second NMOS transistor 12, a first resistor 13, and a second resistor 14. The differential circuit 20A includes a first NPN transistor 21, a second NPN transistor 22, and a tail current source 23. The voltage booster 30 provides a potential equal to or higher than the power supply potential to each gate of the first NMOS transistor 11 and the second NMOS transistor 12.

### TECHNICAL FIELD

The present disclosure relates to a voltage-current conversion device and a current source device.

### BACKGROUND ART

The voltage-current conversion devices described in Patent Literatures 1 and 2 output a current signal corresponding to input differential voltage signals. These voltage-current conversion devices are particularly laser drivers that supply a driving current to a laser diode to emit light, and are intended to supply a driving current to a vertical cavity surface emitting laser (VCSEL) among laser diodes.

As described in these literatures, a voltage-current conversion device generally includes a differential circuit comprising two NPN transistors that form an input differential pair to which differential voltage signals are input, and a current supply circuit provided between these two NPN transistors and a high potential first reference potential supply terminal.

The current supply circuit of the voltage-current conversion device described in Patent Literature 1 includes a PMOS transistor operating in the saturation region. The current supply circuit of the voltage-current conversion device described in Patent Literature 2 includes a PMOS transistor operating in the linear region. A PMOS transistor is a P-channel metal-oxide-semiconductor (MOS) field-effect transistor (FET).

Not limited to voltage-current conversion devices that output a current signal corresponding to input differential voltage signals, current source devices that supply current to a load circuit also include PMOS transistors.

### CITATION LIST

### Patent Literature

Patent Literature 1: US Patent Application Publication No. 2022/0190554

Patent Literature 2: U.S. Pat. No. 9,570,917

### SUMMARY OF INVENTION

### Technical Problem

PMOS transistors have a large capacitance seen from the gate due to the Miller effect, and the frequency characteristics of feedback control are poor, making high-speed operation difficult. PMOS transistors operating in the saturation region have large transistor sizes to carry the required current, resulting in large parasitic capacitance, making high-speed operation even more difficult during large current amplitude operation. PMOS transistors operating in the linear region have a large Vds dependence on the current value, resulting in low output impedance due to feedback control, making large current amplitude operation difficult. Therefore, conventional voltage-current conversion devices and current source devices have difficulty achieving high-speed operation and large current amplitude output.

The present invention has been made to solve the above problems and aims to provide a voltage-current conversion device and a current source device that can easily achieve high-speed operation and large current amplitude output.

### Solution to Problem

A first aspect of the voltage-current conversion device of the present invention includes: (1) a current supply circuit including: a first NMOS transistor and a second NMOS transistor, each having their respective drains connected to a first reference potential supply terminal that supplies a first reference potential; a first resistor provided between a source of the first NMOS transistor and a first node; and a second resistor provided between a source of the second NMOS transistor and a second node; wherein gates of the first NMOS transistor and the second NMOS transistor are connected to each other; (2) a differential circuit including: a first NPN transistor having a collector connected to the first node; a second NPN transistor having a collector connected to the second node; a tail current source provided between a second reference potential supply terminal, which supplies a second reference potential lower than the first reference potential, and emitters of both of the first NPN transistor and the second NPN transistor; (3) a voltage booster configured to provide a potential equal to or higher than the first reference potential to each gate of the first NMOS transistor and the second NMOS transistor; and (4) a controller configured to control the potential provided by the voltage booster to each gate of the first NMOS transistor and the second NMOS transistor based on a current flowing through the first resistor or a potential of the first node. The voltage-current conversion device inputs differential voltage signals to respective bases of the first NPN transistor and the second NPN transistor, and a current signal corresponding to these differential voltage signals is output from the first node. Note that the NMOS transistor is an N-channel metal-oxide-semiconductor (MOS) field-effect transistor (FET). The NPN transistor is an NPN bipolar transistor.

A second aspect of the voltage-current conversion device of the present invention includes: (1) a current supply circuit including: a first NMOS transistor and a second NMOS transistor, each having a drain connected to a first reference potential supply terminal that supplies a first reference potential, wherein gates of the first NMOS transistor and the second NMOS transistor are connected to each other; (2) a differential circuit including: a first NPN transistor having a collector connected to a source of the first NMOS transistor, a second NPN transistor having a collector connected to a source of the second NMOS transistor, and a tail current source provided between a second reference potential supply terminal, which supplies a second reference potential lower than the first reference potential, and emitters of both of the first NPN transistor and the second NPN transistor; (3) a first resistor provided between the source of the first NMOS transistor and a first node; (4) a voltage booster configured to provide a potential equal to or higher than the first reference potential to each gate of the first NMOS transistor and the second NMOS transistor; and (5) a controller configured to control the potential provided by the voltage booster to each gate of the first NMOS transistor and the second NMOS transistor based on a current flowing through the resistor or a potential of the first node. The voltage-current conversion device inputs differential voltage signals to respective bases of the first NPN transistor and the second NPN transistor, and a current signal corresponding to these differential voltage signals is output from the first node.

The voltage-current conversion device of the present invention may also have the following aspects.

In a third aspect, in addition to the first or second aspect, the voltage-current conversion device further includes a third resistor provided between the source of the first NMOS transistor and a third node, and a current source provided between the third node and the second reference potential supply terminal. The controller controls the potential provided by the voltage booster to each gate of the first NMOS transistor and the second NMOS transistor, based on a comparison between the current flowing through the first resistor or the potential of the first node, and the current flowing through the third resistor or the potential of the third node.

In a fourth aspect, in addition to the first or second aspect, the voltage-current conversion device further includes a third NMOS transistor having a drain connected to the first reference potential supply terminal; a third resistor provided between a source of the third NMOS transistor and a third node; and a current source provided between the third node and the second reference potential supply terminal. The gates of the first NMOS transistor, the second NMOS transistor, and the third NMOS transistor are mutually connected. The controller controls the potential provided by the voltage booster to each gate of the first NMOS transistor, the second NMOS transistor, and the third NMOS transistor based on a comparison between a current flowing through the first resistor or a potential of the first node and a current flowing through the third resistor or a potential of the third node.

In a fifth aspect, in addition to any of the first to fourth aspects, the first NMOS transistor and the second NMOS transistor are both N-type LDMOS transistors.

In a sixth aspect, in addition to any of the first to fourth aspects, the first NMOS transistor and the second NMOS transistor each have a triple-well structure, and a resistor is provided between each P-well of the first and second NMOS transistors and the first node.

In a seventh aspect, in addition to any of the first to fourth aspects, the first NMOS transistor and the second NMOS transistor each have a triple-well structure, and a resistor is provided between each P-well of the first and second NMOS transistors and the source of the first NMOS transistor.

In an eighth aspect, in addition to any of the first to fourth aspects, the first NMOS transistor and the second NMOS transistor each have a triple-well structure, and a voltage source is provided between each P-well of the first and second NMOS transistors and the first reference potential supply terminal.

In a ninth aspect, in addition to any of the first to fourth aspects, the first NMOS transistor and the second NMOS transistor each have a triple-well structure, and a diode is provided between each P-well of the first and second NMOS transistors and the first reference potential supply terminal.

In a tenth aspect, in addition to any of the first to ninth aspects, the differential circuit includes a tail current source provided between the second reference potential supply terminal and the emitter of the first NPN transistor, and another tail current source provided between the second reference potential supply terminal and the emitter of the second NPN transistor.

In the eleventh aspect, in addition to the first aspect and any of the third to tenth aspects that include the first aspect, a dummy load is connected to the second node.

In a twelfth aspect, in addition to the third aspect, a resistance value of the third resistor or a current value of the current source is variable.

In a thirteenth aspect, in addition to any of the first to twelfth aspects, the voltage-current conversion device includes a plurality of the current supply circuits, and a number of the current supply circuits connected to the first reference potential supply terminal is variable.

A fourteenth aspect of the voltage-current conversion device of the present invention includes: (1) a current supply circuit including a first NPN transistor and a second NPN transistor, each having their respective collectors connected to a first reference potential supply terminal that supplies a first reference potential; a first resistor provided between an emitter of the first NPN transistor and a first node, and a second resistor provided between an emitter of the second NPN transistor and a second node, wherein bases of the first NPN transistor and the second NPN transistor are connected to each other; (2) a differential circuit including a third NPN transistor having a collector connected to the first node, a fourth NPN transistor having a collector connected to the second node, and a tail current source provided between a second reference potential supply terminal, which supplies a second reference potential lower than the first reference potential, and emitters of both of the third NPN transistor and the fourth NPN transistor; (3) a voltage booster configured to provide a potential equal to or higher than the first reference potential to each base of the first NPN transistor and the second NPN transistor; and (4) a controller configured to control the potential provided by the voltage booster to each base of the first NPN transistor and the second NPN transistor based on a current flowing through the first resistor or a potential of the first node. The voltage-current conversion device inputs differential voltage signals to respective bases of the third NPN transistor and the fourth NPN transistor and outputs a current signal corresponding to these differential voltage signals from the first node.

A fifteenth aspect of the voltage-current conversion device of the present invention includes: (1) a current supply circuit including an NMOS transistor having a drain connected to a first reference potential supply terminal that supplies a first reference potential, and a resistor provided between a source of the NMOS transistor and a node; (2) a differential circuit including a first NPN transistor having a collector connected to the node, a second NPN transistor having a collector connected to the first reference potential supply terminal, and a tail current source provided between a second reference potential supply terminal, which supplies a second reference potential lower than the first reference potential, and both emitters of the first NPN transistor and the second NPN transistor; (3) a voltage booster configured to provide a potential equal to or higher than the first reference potential to a gate of the NMOS transistor; and (4) a controller configured to control the potential provided by the voltage booster to the gate of the NMOS transistor based on a current flowing through the resistor or a potential of the node. The voltage-current conversion device inputs differential voltage signals to respective bases of the first NPN transistor and the second NPN transistor and outputs a current signal corresponding to these differential voltage signals from the node.

A current source device of the present invention includes: (1) an NMOS transistor having a drain connected to a reference potential supply terminal that supplies a reference potential; (2) a voltage booster configured to provide a potential equal to or higher than the reference potential to a gate of the NMOS transistor; and (3) a controller configured to control the potential provided by the voltage booster to the gate of the NMOS transistor based on a current or a potential in a load circuit that receives a current output from a source of the NMOS transistor.

### Effects of Invention

According to the present invention, it is possible to provide a voltage-current conversion device and a current source device that can easily achieve high-speed operation and large current amplitude output.

### BRIEF DESCRIPTION OF DRAWINGS

FIG. 1 is a diagram showing the configuration of a voltage-current conversion device 1A.

FIG. 2 is a diagram showing the configuration of a voltage-current conversion device 1B.

FIG. 3 is a diagram showing the configuration of a voltage-current conversion device 1C.

FIG. 4 is a diagram showing an example circuit configuration of a voltage booster 30.

FIG. 5 is a diagram showing an example circuit configuration of a controller 40B.

FIG. 6 is a diagram showing the configuration of a voltage-current conversion device 1D.

FIG. 7 is a diagram showing the configuration of a voltage-current conversion device 1E.

FIG. 8 is a diagram showing the configuration of a voltage-current conversion device 1F.

FIG. 9 is a diagram showing the configuration of a voltage-current conversion device 1G.

FIG. 10 is a diagram showing the configuration of a voltage-current conversion device 1H.

FIG. 11 is a diagram showing the configuration of a voltage-current conversion device 1i.

FIG. 12 is a diagram showing the configuration of a voltage-current conversion device 1J.

FIG. 13 is a diagram showing the configuration of a voltage-current conversion device 1K.

FIG. 14 is a diagram showing the configuration of a voltage-current conversion device 1L.

FIG. 15 is a diagram showing an example configuration of a dummy load 60.

FIG. 16 is a diagram showing the configuration of a voltage-current conversion device 1M.

FIG. 17 is a diagram showing the configuration of a voltage-current conversion device 1N.

FIG. 18 is a diagram showing the configuration of a voltage-current conversion device 1o.

FIG. 19 is a diagram showing the configuration of a voltage-current conversion device 1P.

FIG. 20 is a diagram showing the configuration of a current source device 1Q.

FIG. 21 is a diagram showing a cross-sectional configuration of a transistor.

### DESCRIPTION OF EMBODIMENTS

Hereafter, embodiments for implementing the present invention will be described in detail with reference to the accompanying drawings. In the description of the drawings, the same reference numbers are assigned to identical elements, and repeated descriptions are omitted.

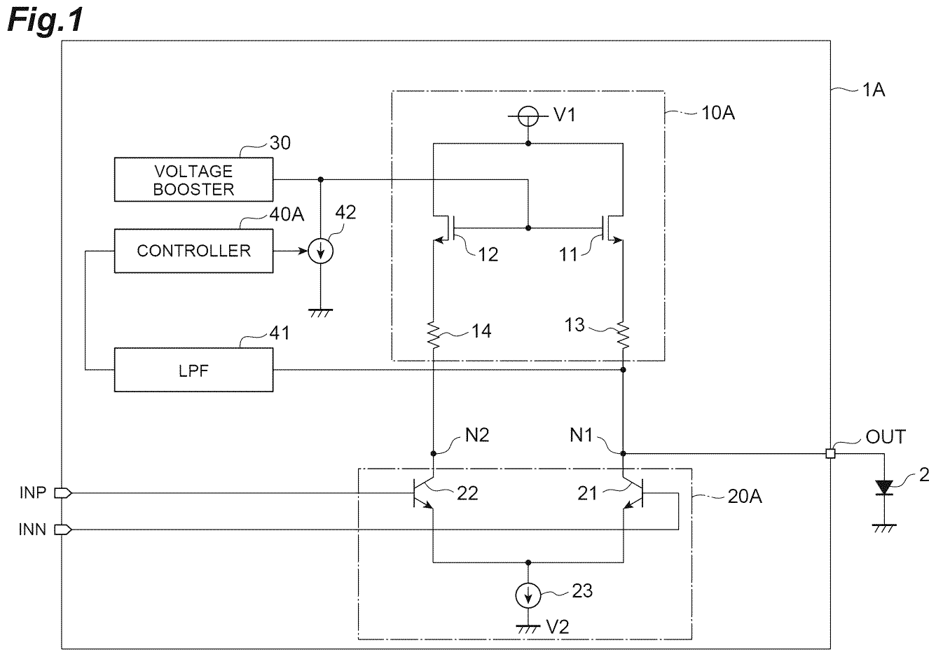

FIG. 1 is a diagram showing the configuration of a voltage-current conversion device 1A. The voltage-current conversion device 1A includes a current supply circuit 10A, a differential circuit 20A, a voltage booster 30, and a controller 40A. The current supply circuit 10A includes a first NMOS transistor 11, a second NMOS transistor 12, a first resistor 13, and a second resistor 14. The differential circuit 20A includes a first NPN transistor 21, a second NPN transistor 22, and a tail current source 23.

The drains of the first NMOS transistor 11 and the second NMOS transistor 12 are connected to a first reference potential supply terminal that supplies a first reference potential (e.g., a power supply potential). The gates of the first NMOS transistor 11 and the second NMOS transistor 12 are connected to each other. The first resistor 13 is provided between the source of the first NMOS transistor 11 and the first node N1. The second resistor 14 is provided between the source of the second NMOS transistor 12 and the second node N2. The characteristics of the first NMOS transistor 11 and the second NMOS transistor 12 are the same. The resistance values of the first resistor 13 and the second resistor 14 are equal.

The collector of the first NPN transistor 21 is connected to the first node N1. The collector of the second NPN transistor 22 is connected to the second node N2. The tail current source 23 is provided between a second reference potential supply terminal that supplies a second reference potential lower than the first reference potential (e.g., a ground potential) and the emitters of the first NPN transistor 21 and the second NPN transistor 22. The characteristics of the first NPN transistor 21 and the second NPN transistor 22 are the same.

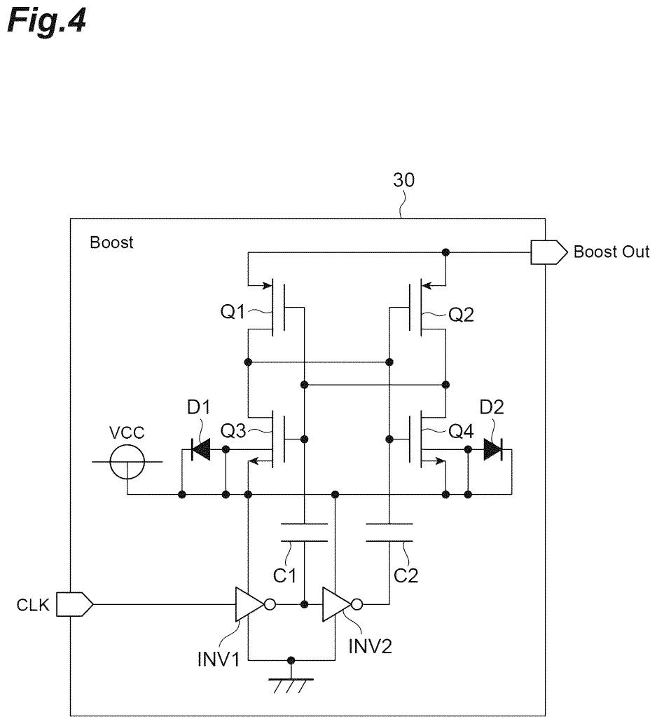

The voltage booster 30 provides a potential equal to or higher than the first reference potential to each gate of the first NMOS transistor 11 and the second NMOS transistor 12. The controller 40A controls the potential provided by the voltage booster 30 to each gate of the first NMOS transistor 11 and the second NMOS transistor 12 based on a current flowing through the first resistor 13 or a potential of the first node N1. An example circuit configuration of the voltage booster 30 is shown in FIG. 4.

The voltage booster 30 shown in FIG. 4 includes PMOS transistors Q1 and Q2, NMOS transistors Q3 and Q4, capacitors C1 and C2, diodes D1 and D2, and inverters INV1 and INV2, and these circuit elements are connected as shown in the figure. The sources of the NMOS transistors Q3 and Q4 are connected to the power supply potential VCC. The sources of the PMOS transistors Q1 and Q2 are connected to the output terminal of the voltage booster 30. A clock signal is input to the input terminal of the first inverter INV1, and the inverted signal of the clock signal is input to the capacitor C1. This inverted signal is input to the second inverter INV2 and inverted again, and the output signal of the second inverter INV2 is input to the capacitor C2.

In the configuration example shown in FIG. 1, a current source 42 is provided between the output terminal of the voltage booster 30 and the second reference potential supply terminal. The controller 40A inputs the potential of the first node N1 via a low-pass filter 41 and controls the current flowing through the current source 42 to adjust the potential provided to the gates of the first NMOS transistor 11 and the second NMOS transistor 12 so that the potential of the first node N1 (i.e., the current flowing through the first resistor 13) becomes a desired value.

The voltage-current conversion device 1A inputs differential voltage signals INP and INN to the bases of the first NPN transistor 21 and the second NPN transistor 22, respectively, and outputs a current signal corresponding to the input differential voltage signals from the first node N1 (output node) to the load 2. The load 2 may be arbitrary, for example, a laser diode, specifically a vertical cavity surface emitting laser diode.

Each of the NMOS transistors 11 and 12 in the current supply circuit 10A operates in the saturation region with a potential equal to or higher than the first reference potential provided to the gate by the voltage booster 30. Further, the current flowing through each of the NMOS transistors 11 and 12 is feedback-controlled to be constant by the controller 40A, which adjusts the amount of current pulled out by the current source 42. Moreover, since a low-pass filter 41 is provided between the first node N1 and the controller 40A, the load capacitance of the feedback system is not seen at the first node N1 (output node).

By performing constant current feedback control on the NMOS transistors 11 and 12 operating in the saturation region, the output impedance is high over a wide bandwidth from DC to high-frequency regions. This is advantageous for large amplitude operation. That is, each of the NMOS transistors 11 and 12 can operate in the saturation region with a potential equal to or higher than the first reference potential provided to the gate by the voltage booster 30. Further, the gate potential of each of the NMOS transistors 11 and 12 is feedback-controlled so that a constant current flow through each of the NMOS transistors 11 and 12 by boosting the voltage with the voltage booster 30 and pulling out the current with the current source 42. As a result, the output impedance increases. Since the output impedance is increased without using an inductor, the output impedance is high even in the low-frequency region.

In contrast to conventional voltage-current conversion devices, including those described in Patent Literatures 1 and 2, which use PMOS transistors in the current supply circuit, the current supply circuit 10A in this embodiment uses NMOS transistors 11 and 12. Therefore, in this embodiment, the Miller effect does not occur, and the capacitance seen from the gate of the NMOS transistors 11 and 12 is not large, making it easy to speed up the loop bandwidth of the feedback control. Therefore, it is easy to maintain high output impedance up to the high-frequency region, enabling high-speed operation and large current amplitude output.

Compared to PMOS transistors, NMOS transistors have higher carrier mobility and require smaller sizes to carry the necessary current, resulting in smaller parasitic capacitance. Even in the high-frequency region beyond the loop bandwidth of the feedback control, it is possible to maintain relatively high output impedance, which is advantageous for high-speed and large amplitude operation. Moreover, since it is a large amplitude operation, even if voltage ripple occurs at the source node of the NMOS transistors 11 and 12, the charging and discharging are fast due to the small parasitic capacitance, making it difficult for inter-symbol interference (ISI) to occur, which is advantageous for high-speed and large amplitude operation. There is no current path to the power supply bypassing the current source, and the power supply current is regulated by the NMOS transistors 11 and 12, so the pattern dependence of the power supply current is small.

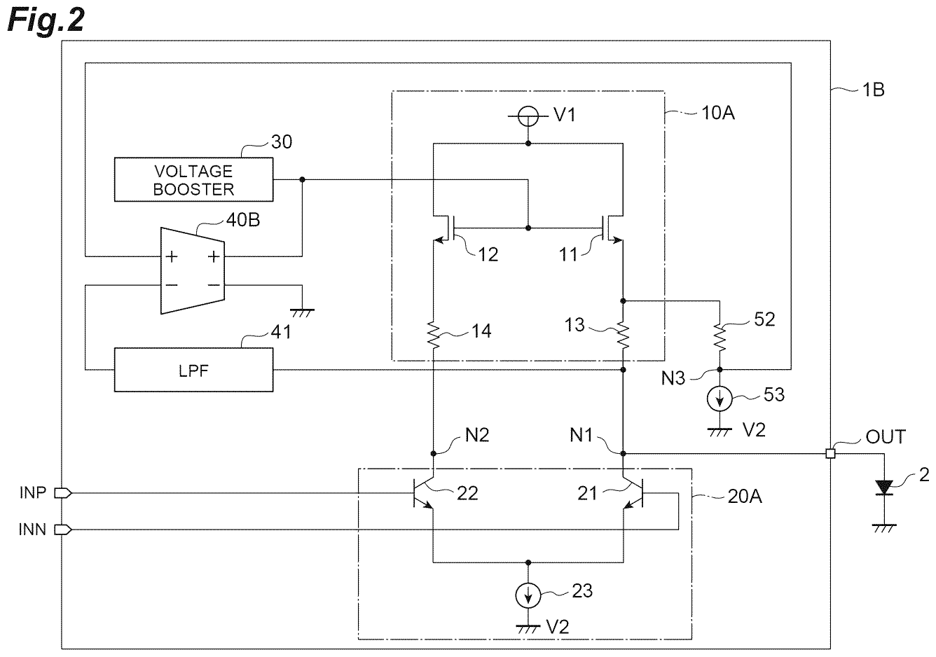

FIG. 2 is a diagram showing the configuration of a voltage-current conversion device 1B. The voltage-current conversion device 1B includes a current supply circuit 10A, a differential circuit 20A, a voltage booster 30, a controller 40B, a third resistor 52, and a current source 53. Compared to the voltage-current conversion device 1A (FIG. 1), the voltage-current conversion device 1B (FIG. 2) differs in that it further includes the third resistor 52 and the current source 53, and it includes the controller 40B instead of the controller 40A and the current source 42.

The third resistor 52 is provided between the source of the first NMOS transistor 11 and the third node N3. The current source 53 is provided between the third node N3 and the second reference potential supply terminal.

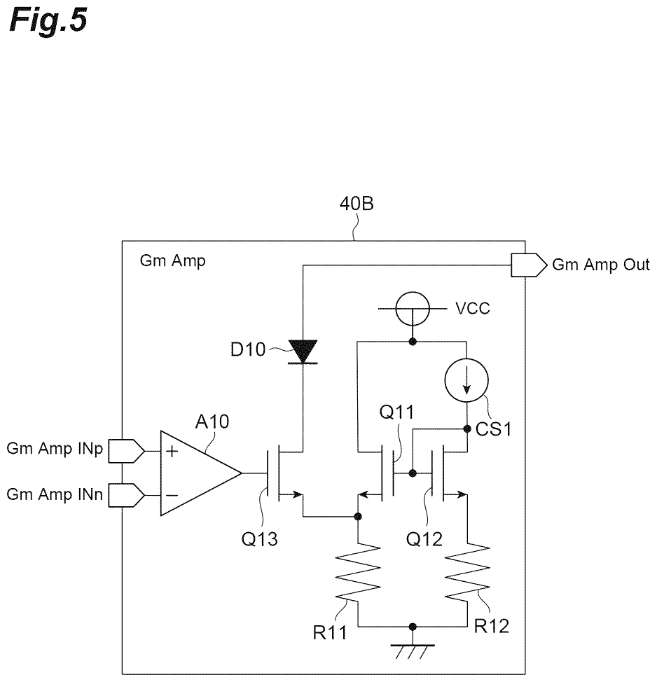

The controller 40B controls the potential provided by the voltage booster 30 to each gate of the NMOS transistors 11 and 12 based on a comparison between the current flowing through the first resistor 13 or the potential at the first node N1 and the current flowing through the third resistor 52 or the potential at the third node N3. In the configuration example shown in this figure, the controller 40B controls the potential provided by the voltage booster 30 to each gate of the NMOS transistors 11 and 12 based on a comparison between the potential of the first node N1 and the potential of the third node N3. The controller 40B can be configured to include a transconductance amplifier (Gm amplifier, current pull-out amplifier). The controller 40B inputs the potential of the node N3 to the non-inverting input terminal and inputs the potential of the first node N1, which has passed through the low-pass filter 41, to the inverting input terminal. An example circuit configuration of the controller 40B is shown in FIG. 5.

The controller 40B includes a first NMOS transistor Q11, a second NMOS transistor Q12, a current source CS1, a first resistor R11, a second resistor R12, a third NMOS transistor Q13, and a differential amplifier A10. These circuit elements are connected as shown in the figure. The gate of the first NMOS transistor Q11 and the gate of the second NMOS transistor Q12 are connected, and this connection point is connected to the drain of the second NMOS transistor Q12. The drain of the second NMOS transistor Q12 is connected to the power supply potential VCC via the current source CS1. The drain of the first NMOS transistor Q11 is connected to the power supply potential VCC. The sources of the first NMOS transistor Q11 and the second NMOS transistor Q12 are connected to the ground potential. The drain of the third NMOS transistor Q13 is connected to the output terminal via the diode D10.

The resistance values of the resistors 13 and 14 are R, and the desired value of the current flowing through the resistor 13 is Ibias. The resistance value of the resistor 52 is set to M times R (M*R), and the current flowing through the current source 53 is set to Ibias divided by M (Ibias/M). The controller 40B performs feedback control on the potential provided to the gates of the NMOS transistors 11, 12 so that the potentials of the first node N1 and the third node N3 are equal. As a result, the potential differences generated across the resistors 13 and 52 are matched, and the current flowing through the resistor 13 can be set to the desired value Ibias.

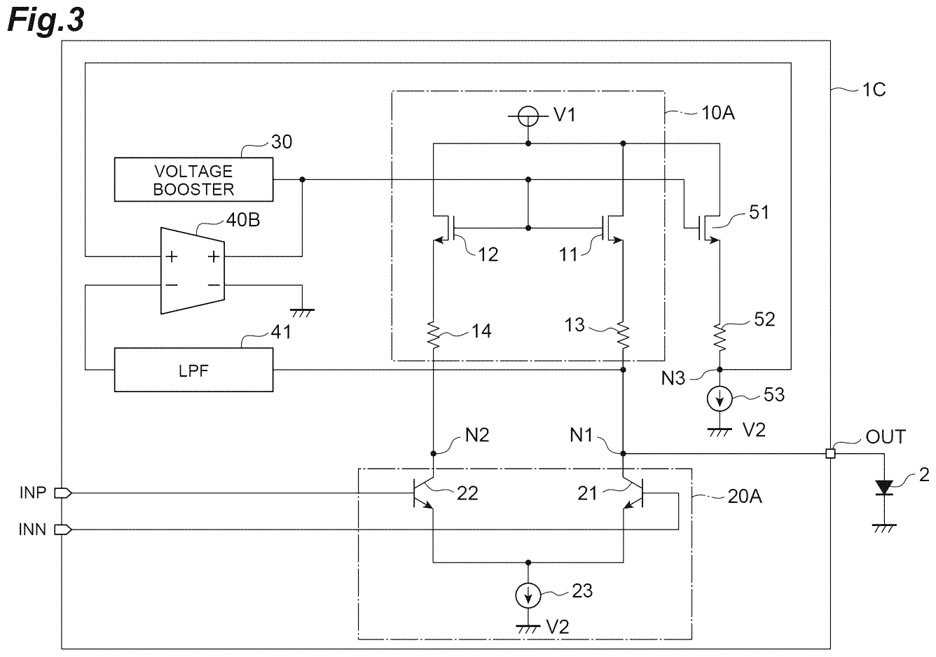

FIG. 3 is a diagram showing the configuration of a voltage-current conversion device 1C. The voltage-current conversion device 1B includes a current supply circuit 10A, a differential circuit 20A, a voltage booster 30, a controller 40B, a third NMOS transistor 51, a third resistor 52, and a current source 53. Compared to the voltage-current conversion device 1A (FIG. 1), the voltage-current conversion device 1C (FIG. 3) differs in that it further includes the third NMOS transistor 51, the third resistor 52, and the current source 53, and it includes the controller 40B instead of the controller 40A and the current source 42.

The drain of the third NMOS transistor 51 is connected to the first reference potential supply terminal. The third resistor 52 is provided between the source of the third NMOS transistor 51 and the third node N3. The current source 53 is provided between the third node N3 and the second reference potential supply terminal. The gates of the NMOS transistors 11, 12, and 51 are connected to each other.

The controller 40B controls the potential provided by the voltage booster 30 to each gate of the NMOS transistors 11, 12, and 51 based on a comparison between the current flowing through the first resistor 13 or the potential at the first node N1 and the current flowing through the third resistor 52 or the potential at the third node N3. In the configuration example shown in this figure, the controller 40B controls the potential provided by the voltage booster 30 to each gate of the NMOS transistors 11, 12, and 51 based on a comparison between the potential of the first node N1 and the potential of the third node N3. The controller 40B can be configured to include a transconductance amplifier (current pull-out amplifier). The controller 40B inputs the potential of the node N3 to the non-inverting input terminal and inputs the potential of the first node N1, which has passed through the low-pass filter 41, to the inverting input terminal.

The gate length of the NMOS transistors 11 and 12 is W, the resistance values of the resistors 13 and 14 are R, and the desired value of the current flowing through the resistor 13 is Ibias. The gate length of the NMOS transistor 51 is set to W/M, the resistance value of the resistor 52 is set to M times R (M*R), and the current flowing through the current source 53 is set to Ibias divided by M (Ibias/M). The controller 40B performs feedback control on the potential provided to the gates of the NMOS transistors 11, 12, and 51 so that the potentials of the first node N1 and the third node N3 are equal. As a result, the potential differences generated across the NMOS transistor 11 and the resistor 13, and the NMOS transistor 51 and the resistor 52 are matched, and the current flowing through the resistor 13 can be set to the desired value Ibias.

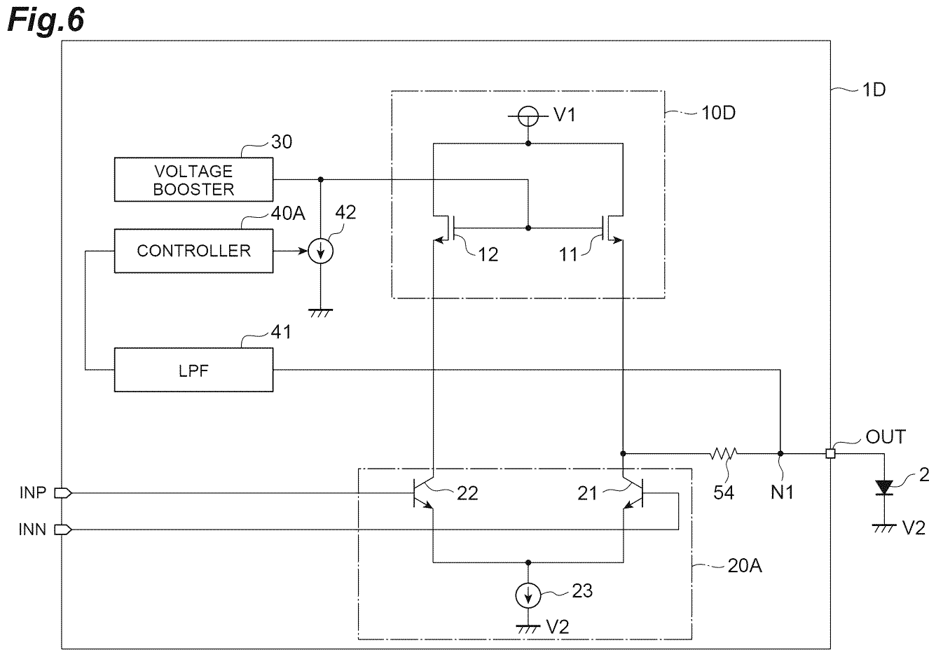

FIG. 6 is a diagram showing the configuration of a voltage-current conversion device 1D. The voltage-current conversion device 1D includes a current supply circuit 10D, a differential circuit 20A, a voltage booster 30, a controller 40A, and a resistor 54. Compared to the voltage-current conversion device 1A (FIG. 1), the voltage-current conversion device 1D (FIG. 6) differs in that it includes the current supply circuit 10D instead of the current supply circuit 10A and further includes the resistor 54.

The current supply circuit 10D includes the first NMOS transistor 11 and the second NMOS transistor 12. The drains of the first NMOS transistor 11 and the second NMOS transistor 12 are connected to the first reference potential supply terminal that supplies the first reference potential (e.g., a power supply potential). The gates of the first NMOS transistor 11 and the second NMOS transistor 12 are connected to each other. The characteristics of the first NMOS transistor 11 and the second NMOS transistor 12 are the same. The resistance values of the first resistor 13 and the second resistor 14 are equal.

The differential circuit 20A includes the first NPN transistor 21, the second NPN transistor 22, and the tail current source 23. The collector of the first NPN transistor 21 is connected to the source of the first NMOS transistor 11. The collector of the second NPN transistor 22 is connected to the source of the second NMOS transistor 12. The tail current source 23 is provided between the second reference potential supply terminal that supplies a second reference potential lower than the first reference potential (e.g., a ground potential) and the emitters of the first NPN transistor 21 and the second NPN transistor 22. The characteristics of the first NPN transistor 21 and the second NPN transistor 22 are the same.

The resistor 54 is provided between the source of the first NMOS transistor 11 and the first node N1.

The voltage booster 30 provides a potential equal to or higher than the first reference potential to each gate of the first NMOS transistor 11 and the second NMOS transistor 12. The controller 40A controls the potential provided by the voltage booster 30 to each gate of the first NMOS transistor 11 and the second NMOS transistor 12 based on a current flowing through the resistor 54 or a potential of the first node N1.

In the configuration example shown in this figure, a current source 42 is provided between the output terminal of the voltage booster 30 and the second reference potential supply terminal. The controller 40A inputs the potential of the first node N1 via a low-pass filter 41 and controls the current flowing through the current source 42 to adjust the potential provided to the gates of the first NMOS transistor 11 and the second NMOS transistor 12 so that the potential of the first node N1 (i.e., the current flowing through the resistor 54) becomes a desired value.

The voltage-current conversion device 1D inputs differential voltage signals INP and INN to the bases of the first NPN transistor 21 and the second NPN transistor 22, respectively, and outputs a current signal corresponding to the input differential voltage signals from the first node N1 (output node) to the load 2. The load 2 may be arbitrary, for example, a laser diode, specifically a vertical cavity surface emitting laser diode.

Compared to the voltage-current conversion device 1A (FIG. 1), the voltage-current conversion device 1D (FIG. 6) differs in the position where the resistor for detecting the potential is provided. Since the voltage-current conversion device 1D (FIG. 6) detects the current output from the first node N1 (output node) to the load 2 rather than the current flowing through the NMOS transistor 11, it is possible to control the current value more accurately.

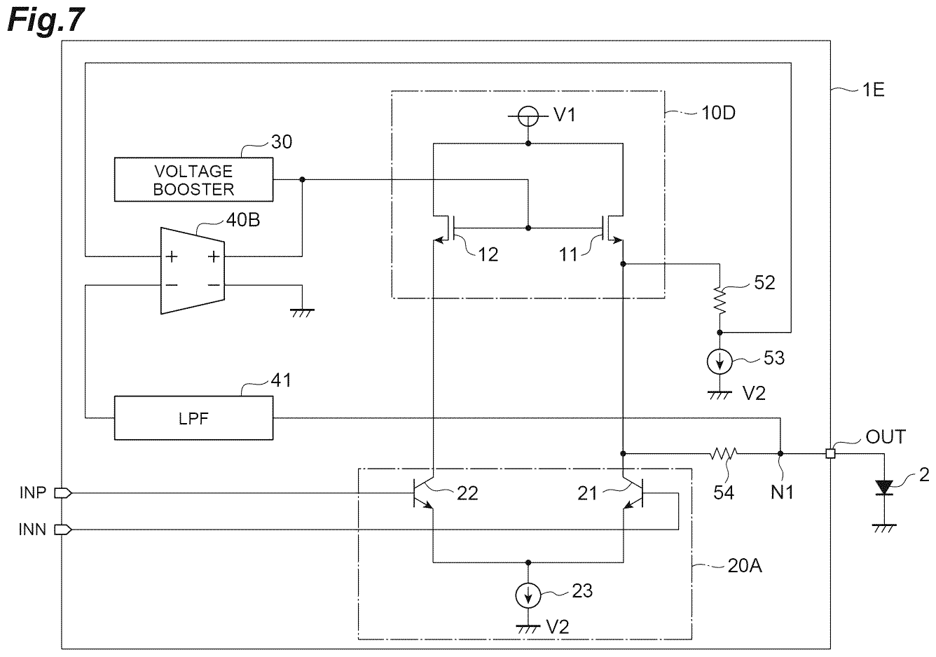

FIG. 7 is a diagram showing the configuration of a voltage-current conversion device 1E. The voltage-current conversion device 1E includes a current supply circuit 10D, a differential circuit 20A, a voltage booster 30, a controller 40B, a third resistor 52, a current source 53, and a resistor 54. Compared to the voltage-current conversion device 1B (FIG. 2), the voltage-current conversion device 1E (FIG. 7) differs in that it includes the current supply circuit 10D instead of the current supply circuit 10A and further includes the resistor 54. The configuration of the current supply circuit 10D and the position of the resistor 54 are the same as those of the voltage-current conversion device 1D (FIG. 6). Compared to the voltage-current conversion device 1B (FIG. 2), the voltage-current conversion device 1E (FIG. 7) differs in the position where the resistor for detecting the potential is provided. Since the voltage-current conversion device 1E (FIG. 7) detects the current output from the first node N1 (output node) to the load 2 rather than the current flowing through the NMOS transistor 11, it is possible to control the current value more accurately.

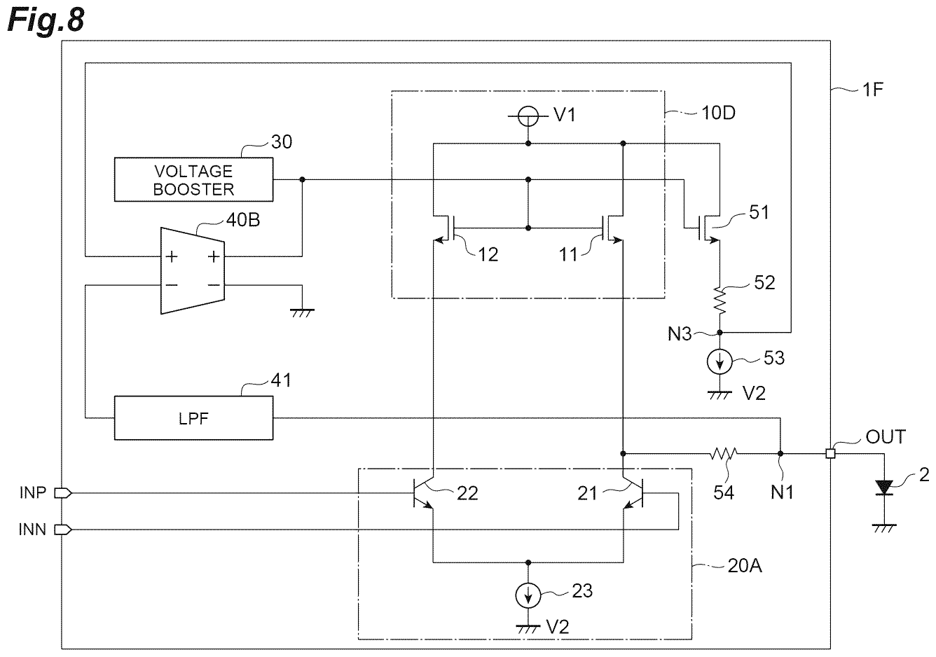

FIG. 8 is a diagram showing the configuration of a voltage-current conversion device 1F. The voltage-current conversion device 1F includes a current supply circuit 10D, a differential circuit 20A, a voltage booster 30, a controller 40B, a third NMOS transistor 51, a third resistor 52, a current source 53, and a resistor 54. Compared to the voltage-current conversion device 1C (FIG. 3), the voltage-current conversion device 1F (FIG. 8) differs in that it includes the current supply circuit 10D instead of the current supply circuit 10A and further includes the resistor 54. The configuration of the current supply circuit 10D and the position of the resistor 54 are the same as those of the voltage-current conversion device 1D (FIG. 6). Compared to the voltage-current conversion device 1C (FIG. 3), the voltage-current conversion device 1F (FIG. 8) differs in the position where the resistor for detecting the potential is provided. Since the voltage-current conversion device 1F (FIG. 8) detects the current output from the first node N1 (output node) to the load 2 rather than the current flowing through the NMOS transistor 11, it is possible to control the current value more accurately.

Hereinafter, various modified configurations of the voltage-current conversion device will be described. In describing the configurations of the modified examples, the description will be based on the configurations of the voltage-current conversion device 1A (FIG. 1), the voltage-current conversion device 1B (FIG. 2), the voltage-current conversion device 1C (FIG. 3), the voltage-current conversion device 1D (FIG. 6), the voltage-current conversion device 1E (FIG. 7), and the voltage-current conversion device 1F (FIG. 8), but configurations based on other configurations are also possible. Moreover, it is also possible to combine the configurations of two or more of the modified examples described below.

The NMOS transistors 11 and 12 (and the NMOS transistor 51) may have a normal configuration, but preferably, they may be N-type LDMOS transistors or have a triple-well structure. By using these NMOS transistors, the high voltage tolerance characteristics can be improved. An N-type LDMOS transistor includes an N-type source region and an N-type drain region, and an N-channel is formed in a P-type region (P-well) directly under the gate electrode. An N-type drift region is formed around the drain region. The structure of LDMOS is described, for example, in U.S. Pat. Nos. 8,357,986 and 10,833,164, and these documents can be incorporated by reference as necessary. Many types of LDMOS are known.

N-type LDMOS transistors are expected to have lower on-resistance and better high-frequency characteristics compared to NMOS transistors with similar voltage tolerance, which is beneficial when used in combination with the voltage booster 30. N-type LDMOS transistors have a structure that reduces the electric field gradient per unit length between the drain and the gate, resulting in higher voltage tolerance even with the same gate length. For example, while the voltage tolerance of a CMOS with a gate length of 0.13 μm is 1.5 V, the voltage tolerance of an LDMOS with the same gate length can exceed 5 V. A CMOS with a voltage tolerance exceeding 5 V would have a design rule of 0.4 μm or more, resulting in increased size and increased parasitic capacitance and resistance. In applications requiring high voltage tolerance, using LDMOS can achieve circuits with less parasitic resistance and capacitance and better high-frequency characteristics compared to CMOS.

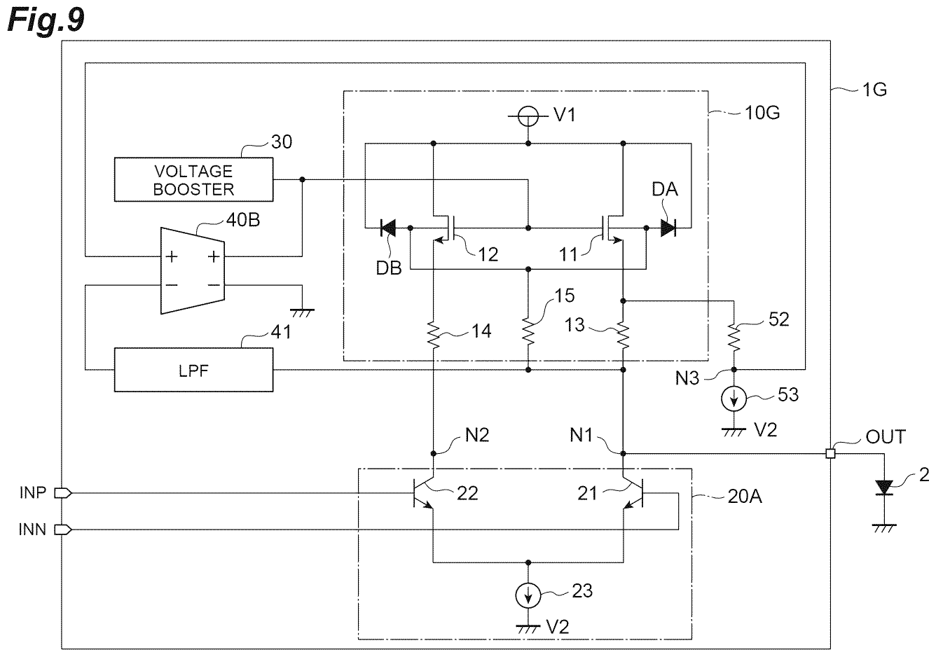

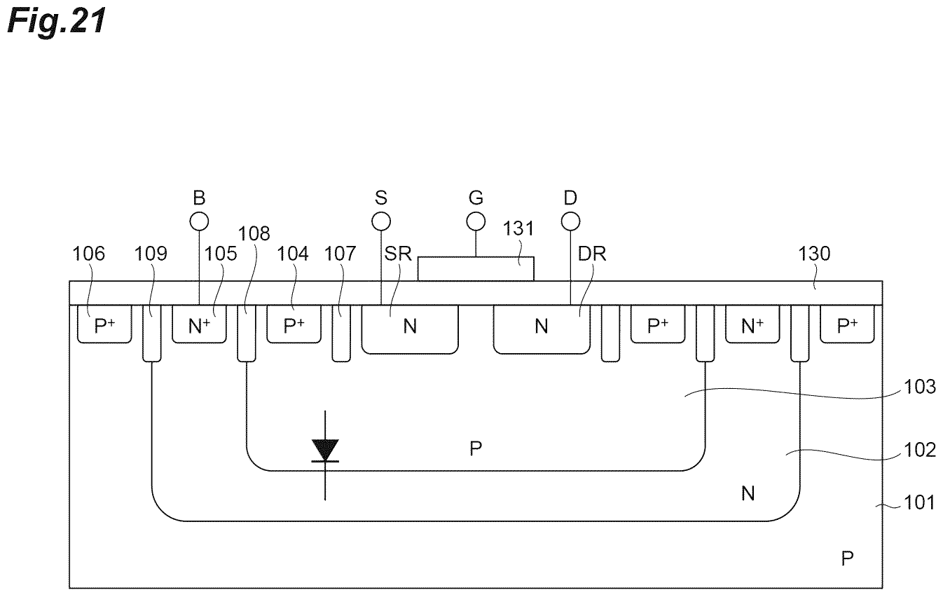

An NMOS transistor with a triple-well structure (see FIG. 21) includes a deep N-well 102 and a P-well 103 formed sequentially on a P-type substrate 101, with a drain region DR connected to a drain electrode terminal D and a source region SR connected to a source electrode terminal S formed within the P-well 103. A P-well contact (P-type contact region 104) is formed to electrically connect the P-well 103 to an external circuit. An N-type contact region 105 is formed within the N-well 102, and a P-type contact region 106 is formed within the surface region of the P-type semiconductor substrate 101. Appropriate bias potentials can be applied to these contact regions. Isolation regions 107, 108, and 109 are formed near the surface of each well to block electrical conduction between the contact regions. An insulating film 130 is formed on the surface of the semiconductor substrate 1, and a gate electrode 131 is formed on the insulating film 130. A gate electrode terminal G is connected to the gate electrode 131. Multiple P-wells 103 can be formed within a single N-well 102. A parasitic diode is formed between the P-well 103 and the N-well, with the P-well as the anode and the N-well as the cathode, and the cathode of the parasitic diode can be connected to a specific potential via the N-type contact region 105 and the contact terminal B. When a potential difference exceeding the power supply voltage is applied between the gate and the substrate of a normal NMOS transistor, there is a risk of gate breakdown. In contrast, using an NMOS transistor with a triple-well structure can avoid voltage tolerance issues. When using NMOS transistors 11 and 12 (and NMOS transistor 51) with a triple-well structure, it is preferable to apply bias as shown in FIGS. 9 to 12. The configurations shown in these figures are modified examples based on the voltage-current conversion device 1B (FIG. 2).

In the configuration of the voltage-current conversion device 1G shown in FIG. 9, the P-wells of the NMOS transistors 11 and 12 with a triple-well structure (see P-well 103 in FIG. 21) in the current supply circuit 10G are connected to the first reference potential supply terminal via parasitic diodes (DA, DB) formed between the wells and are also connected to the first node N1 via a resistor 15.

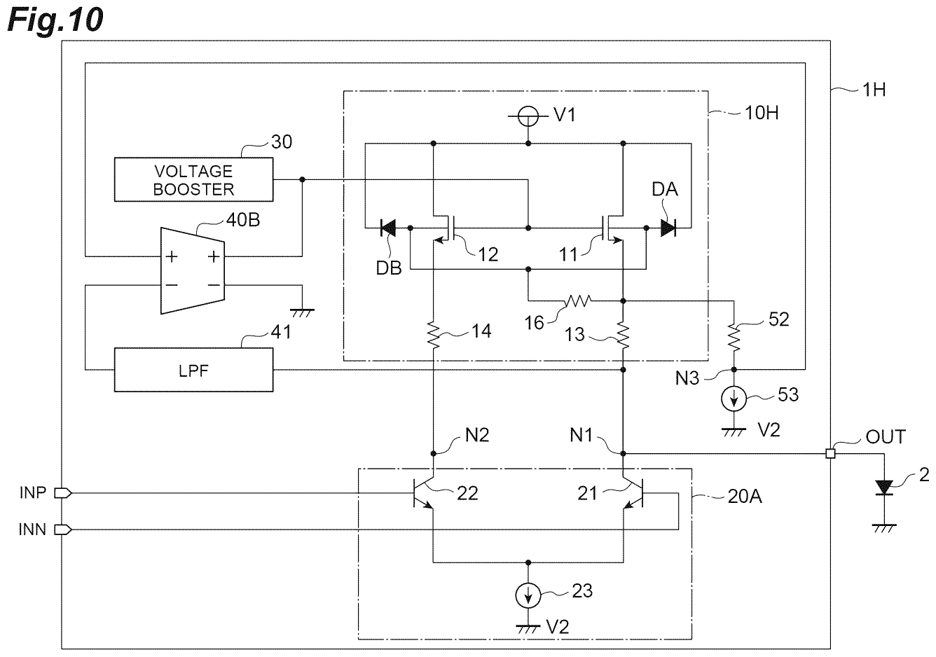

In the configuration of the voltage-current conversion device 1H shown in FIG. 10, the P-wells of the NMOS transistors 11 and 12 with a triple-well structure (see P-well 103 in FIG. 21) in the current supply circuit 10H are connected to the first reference potential supply terminal via parasitic diodes (DA, DB) formed between the wells and are also connected to the source of the NMOS transistor 11 via a resistor 16.

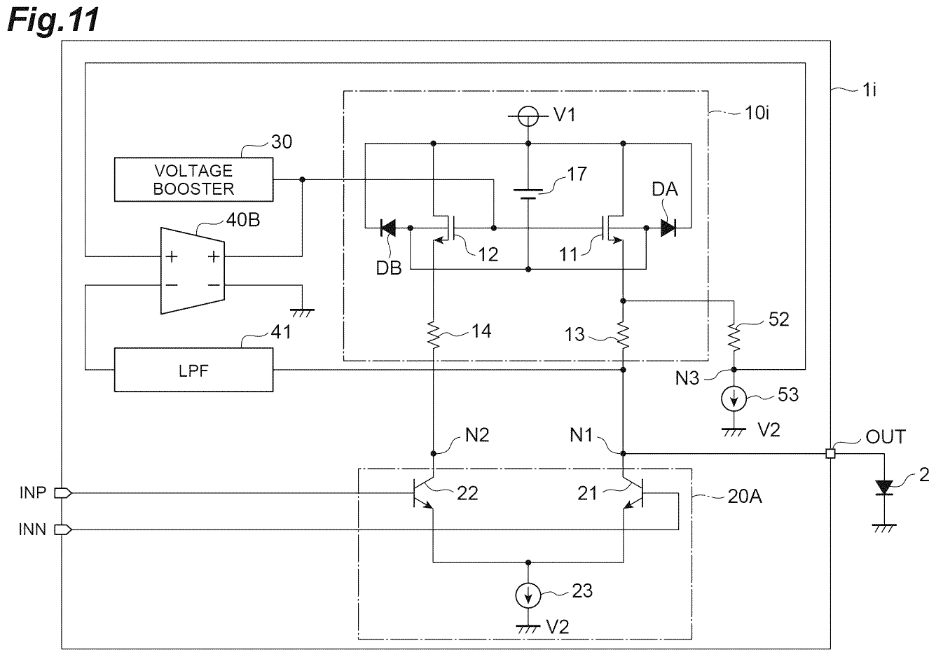

In the configuration of the voltage-current conversion device 1i shown in FIG. 11, the P-wells of the NMOS transistors 11 and 12 with a triple-well structure (see P-well 103 in FIG. 21) in the current supply circuit 10i are connected to the first reference potential supply terminal via parasitic diodes (DA, DB) formed between the wells and are also connected to the first reference potential supply terminal via a voltage source 17.

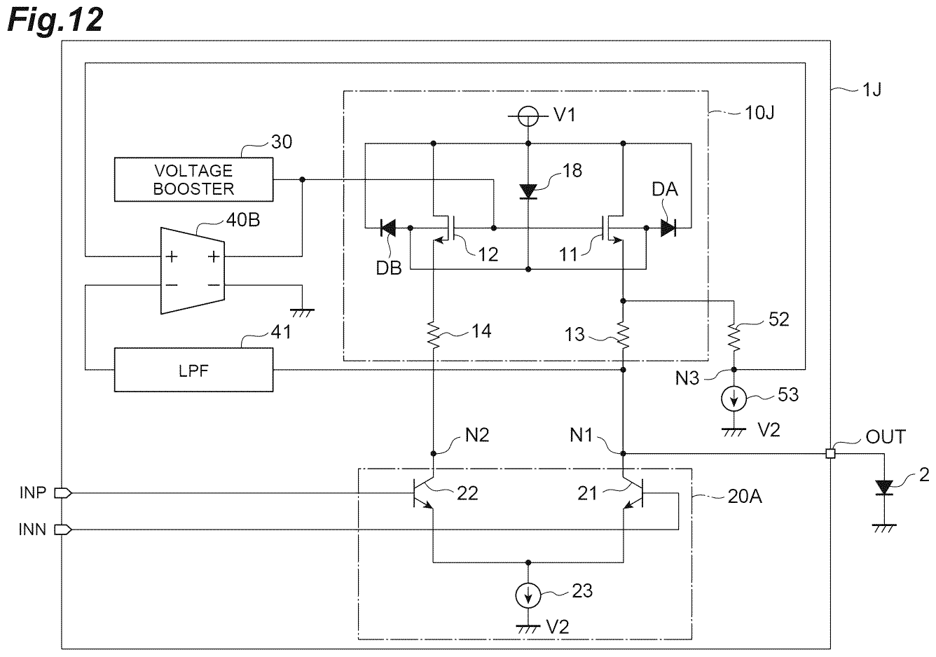

In the configuration of the voltage-current conversion device 1J shown in FIG. 12, the P-wells of the NMOS transistors 11 and 12 with a triple-well structure (see P-well 103 in FIG. 21) in the current supply circuit 10J are connected to the first reference potential supply terminal via parasitic diodes (DA, DB) formed between the wells and are also connected to the first reference potential supply terminal via a diode 18.

By adopting the configurations shown in FIGS. 9 to 12, it is possible to suppress the application of a potential difference exceeding the power supply voltage between the gate and the substrate of each of the NMOS transistors 11 and 12, thereby avoiding voltage tolerance issues. Compared to the configuration shown in FIG. 9, the configuration shown in FIG. 10 is advantageous in that the substrate potential is higher, the increase in Vth due to the substrate bias effect is mitigated, and there is no potential difference between the source and the substrate, making the parasitic capacitance between the source and the substrate invisible.

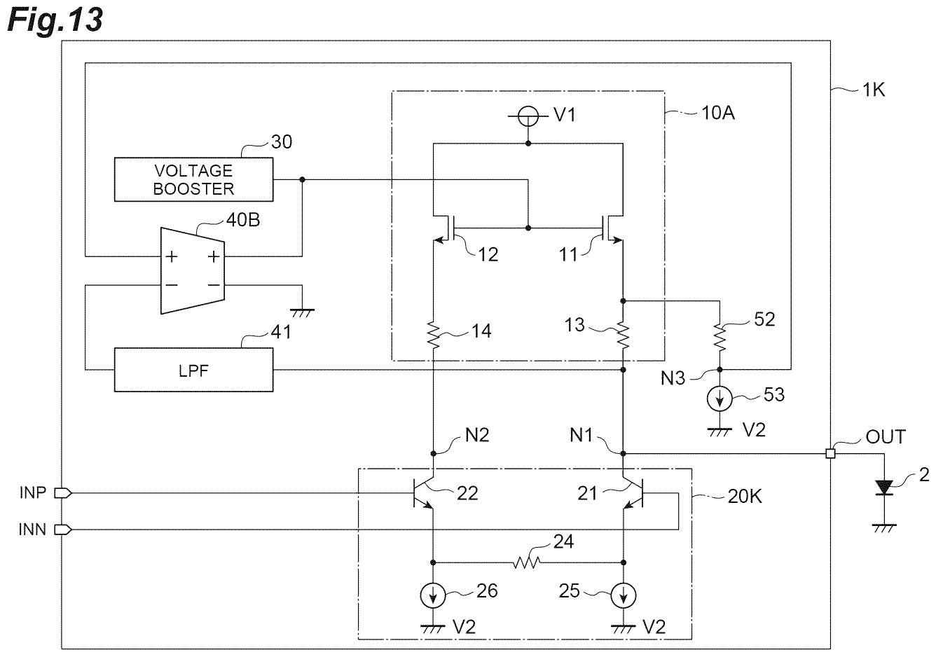

FIG. 13 is a diagram showing the configuration of a voltage-current conversion device 1K. Compared to the voltage-current conversion device 1B (FIG. 2), the voltage-current conversion device 1K (FIG. 13) differs in that it includes a differential circuit 20K instead of the differential circuit 20A. The differential circuit 20K includes a tail current source 25 provided between the second reference potential supply terminal and the emitter of the NPN transistor 21, and a tail current source 26 provided between the second reference potential supply terminal and the emitter of the NPN transistor 22. A resistor 24 is provided between the emitters of the NPN transistors 21 and 22. With this configuration, emitter degeneration occurs, and the transconductance of the differential pair is degenerated. The gain is suppressed, the input dynamic range is increased, and the linear operation of the voltage-current conversion device 1K is enabled.

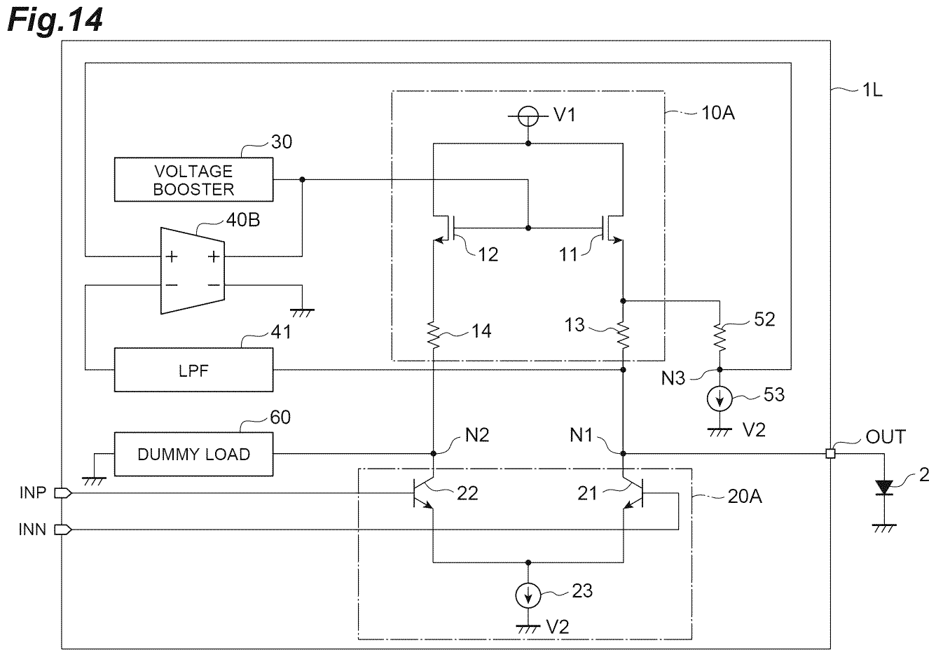

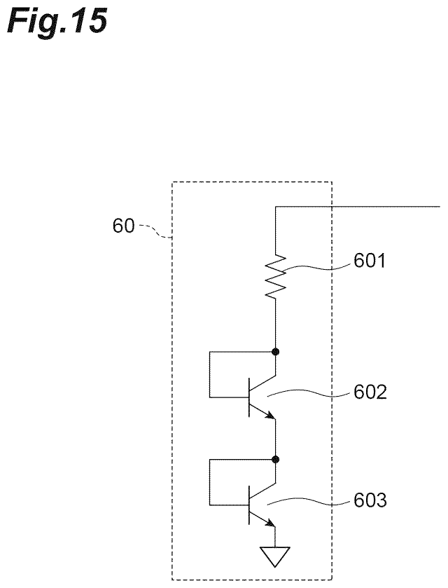

FIG. 14 is a diagram showing the configuration of a voltage-current conversion device 1L. Compared to the voltage-current conversion device 1B (FIG. 2), the voltage-current conversion device 1L (FIG. 14) differs in that it further includes a dummy load 60. The dummy load 60 is connected to the second node N2 and has an impedance similar to that of the load 2. For example, when the load 2 is a laser diode, the dummy load 60 can be configured by connecting a resistor 601 and diodes 602 and 603 in series, as shown in FIG. 15. The diodes 602 and 603 can be configured by connecting the collector and base of an NPN transistor to each other. By adopting such a configuration with a dummy load 60, the symmetry of the circuit operation is improved, the pattern dependence of the power supply current is suppressed, and it is effective in suppressing power supply noise.

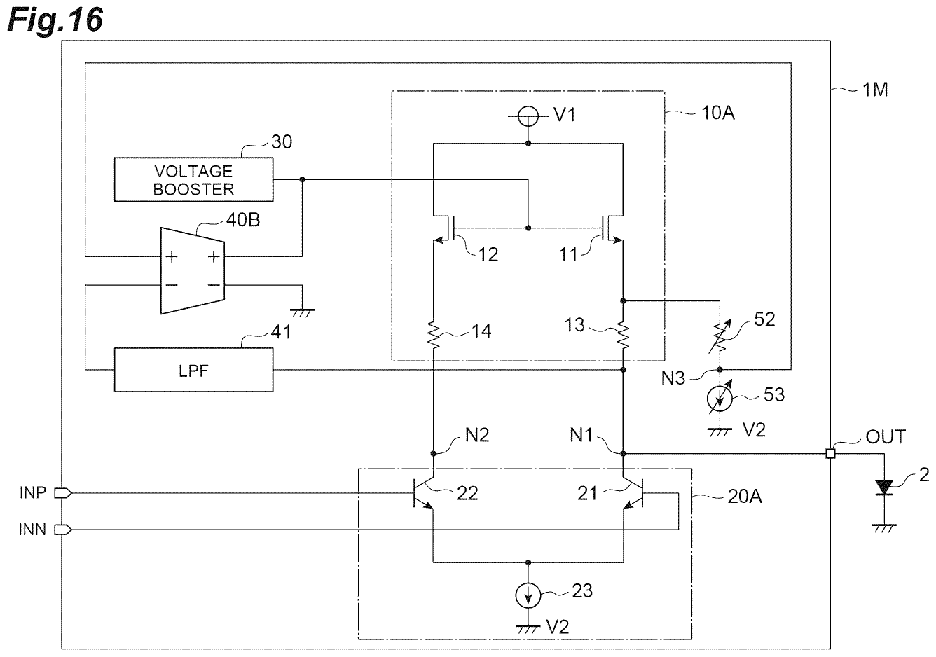

FIG. 16 is a diagram showing the configuration of a voltage-current conversion device 1M. Compared to the voltage-current conversion device 1B (FIG. 2), the voltage-current conversion device 1M (FIG. 16) differs in that the resistance value of the third resistor 52 or the current value of the current source 53 is variable. By adopting such a configuration, it is possible to adjust the current flowing through the NMOS transistors 11 and 12.

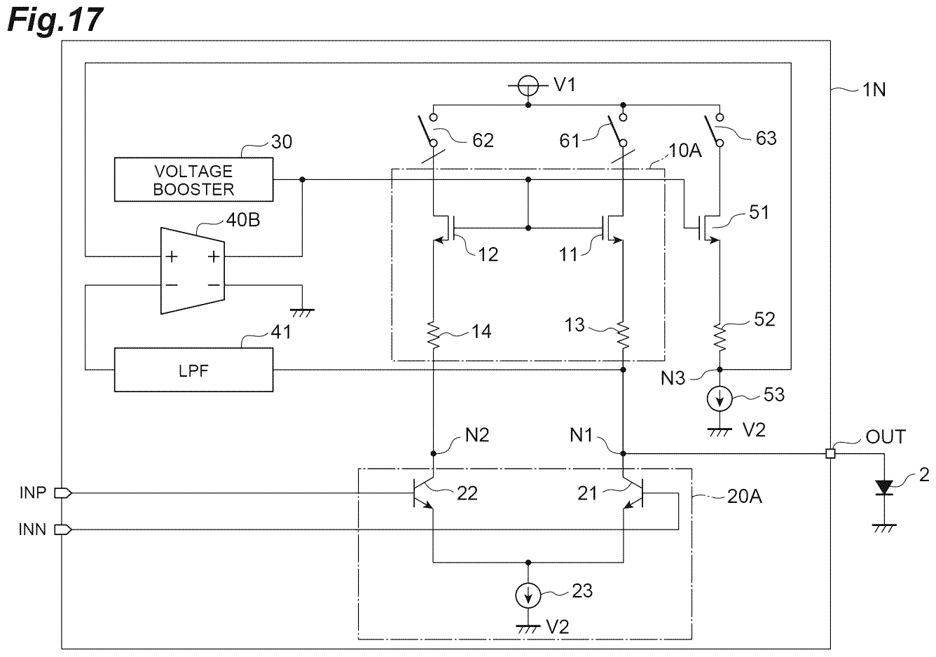

FIG. 17 is a diagram showing the configuration of a voltage-current conversion device 1N. Compared to the voltage-current conversion device 1C (FIG. 3), the voltage-current conversion device 1N (FIG. 17) differs in that it includes a plurality of current supply circuits 10A. Switches 61 and 62 are provided between each of the current supply circuits 10A and the first reference potential supply terminal. A pair of switches 61 and 62 is provided for each current supply circuit 10A. The number of current supply circuits 10A connected to the first reference potential supply terminal, among the multiple current supply circuits 10A, can be varied based on the number of pairs of switches 61 and 62 that are turned on among the multiple pairs of switches 61 and 62. By adopting such a configuration, it is possible to change the size ratio with the reference path (the third NMOS transistor 51, the third resistor 52, and the current source 53), thereby adjusting the total current value flowing through the NMOS transistors 11 and 12. Even if the current value is adjusted, the operating point of the NMOS transistors 11 and 12 is always kept constant, making it easy to widen the current variable range. Note that the switch 63 provided between the drain of the third NMOS transistor 51 and the first reference potential supply terminal is a replica of the switches 61 and 62 provided between the drains of the NMOS transistors 11 and 12 and the first reference potential supply terminal, and it is always in the on state during use and may not be provided.

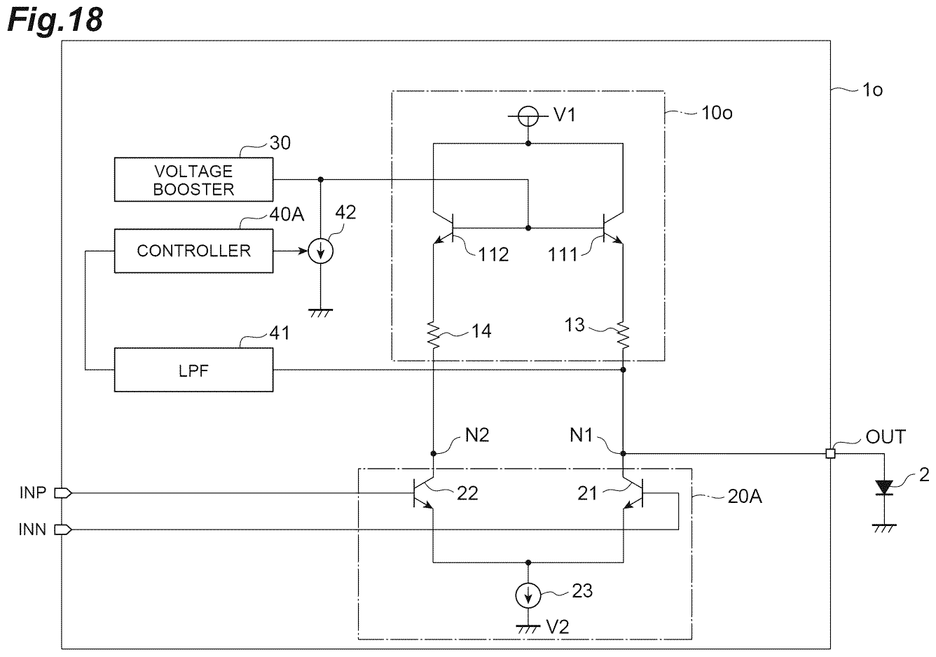

FIG. 18 is a diagram showing the configuration of a voltage-current conversion device 10. Compared to the voltage-current conversion device 1A (FIG. 1), the voltage-current conversion device 10 (FIG. 18) differs in that it includes a current supply circuit 10o instead of the current supply circuit 10A. The current supply circuit 10o includes NPN transistors 111 and 112 and resistors 13 and 14.

The collectors of the NPN transistors 111 and 112 are connected to the first reference potential supply terminal that supplies the first reference potential (e.g., a power supply potential). The bases of the NPN transistors 111 and 112 are connected to each other. The resistor 13 is provided between the emitter of the NPN transistor 111 and the node N1. The resistor 14 is provided between the emitter of the NPN transistor 112 and the node N2. The characteristics of the NPN transistors 111 and 112 are the same. The resistance values of the resistors 13 and 14 are equal.

The voltage booster 30 provides a potential equal to or higher than the first reference potential to each base of the NPN transistors 111 and 112. The controller 40A controls the potential provided by the voltage booster 30 to each base of the NPN transistors 111 and 112 based on a current flowing through the resistor 13 or a potential of the node N1.

This voltage-current conversion device includes a current supply circuit 10o comprising a first NPN transistor 111 and a second NPN transistor 112, each having their respective collectors connected to a first reference potential supply terminal V1 that supplies a first reference potential, a first resistor 13 provided between an emitter of the first NPN transistor 111 and a first node N1, and a second resistor 14 provided between an emitter of the second NPN transistor 112 and a second node N2, wherein bases of the first NPN transistor 111 and the second NPN transistor 112 are connected to each other; a differential circuit 20A comprising a third NPN transistor 21 having a collector connected to the first node N1, a fourth NPN transistor 22 having a collector connected to the second node N2, and a tail current source 23 provided between a second reference potential supply terminal V2 that supplies a second reference potential lower than the first reference potential and emitters of each of the third NPN transistor 21 and the fourth NPN transistor 22; a voltage booster 30 configured to provide a potential equal to or higher than the first reference potential to each base of the first NPN transistor 111 and the second NPN transistor 112; and a controller 40A configured to control the potential provided by the voltage booster 30 to each base of the first NPN transistor 111 and the second NPN transistor 112 based on a current flowing through the first resistor 13 or a potential of the first node N1, wherein differential voltage signals are input to bases of the third NPN transistor 21 and the fourth NPN transistor 22, and a current signal corresponding to the differential voltage signals is output from the first node N1.

While the current supply circuit 10A of the voltage-current conversion device 1A (FIG. 1) includes NMOS transistors 11 and 12, the current supply circuit 10o of the voltage-current conversion device 1o (FIG. 18) includes NPN transistors 111 and 112. Even with the latter configuration, it is possible to realize a voltage-current conversion device that can easily achieve high-speed operation and large current amplitude output.

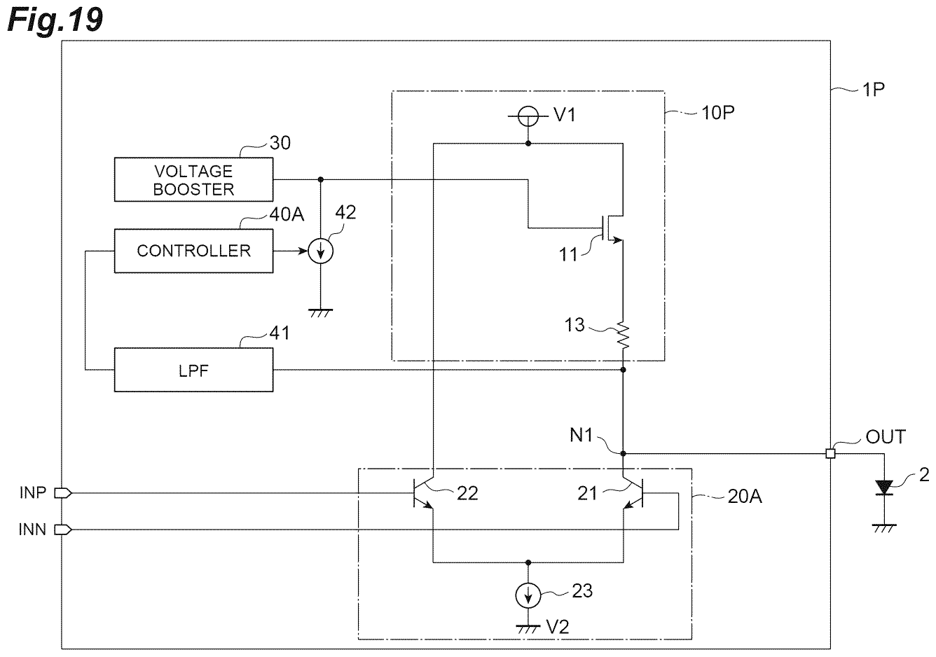

FIG. 19 is a diagram showing the configuration of a voltage-current conversion device 1P. Compared to the voltage-current conversion device 1A (FIG. 1), the voltage-current conversion device 1P (FIG. 19) differs in that it includes a current supply circuit 10P instead of the current supply circuit 10A. The current supply circuit 10P includes an NMOS transistor 11 and a resistor 13.

The drain of the NMOS transistor 11 is connected to the first reference potential supply terminal that supplies the first reference potential (e.g., a power supply potential). The resistor 13 is provided between the source of the NMOS transistor 11 and the node N1. The collector of the NPN transistor 21 is connected to the node N1. The collector of the NPN transistor 22 is connected to the first reference potential supply terminal. The voltage booster 30 provides a potential equal to or higher than the first reference potential to the gate of the NMOS transistor 11. The controller 40A controls the potential provided by the voltage booster to the gate of the NMOS transistor based on a current flowing through the resistor or a potential of the node.

While the current supply circuit 10A of the voltage-current conversion device 1A (FIG. 1) includes two NMOS transistors 11 and 12 and two resistors 13 and 14, the current supply circuit 10P of the voltage-current conversion device 1P (FIG. 19) includes one NMOS transistor 11 and one resistor 13. Even with the latter configuration, it is possible to realize a voltage-current conversion device that can easily achieve high-speed operation and large current amplitude output.

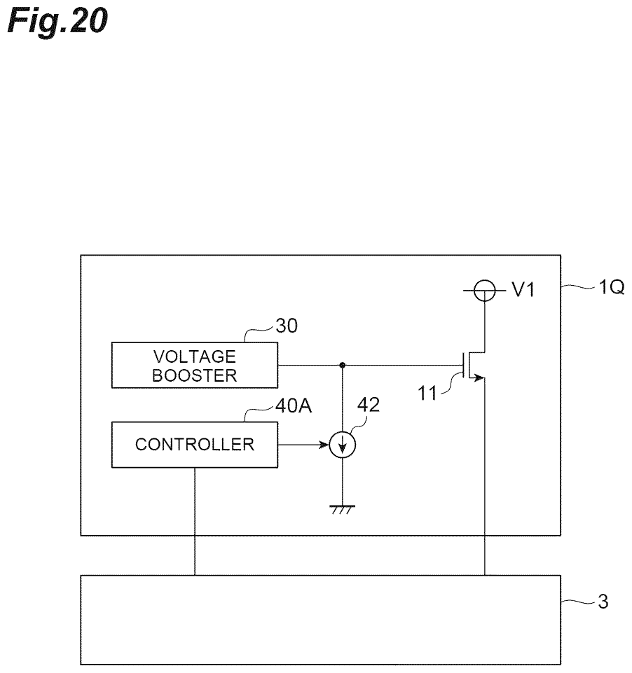

FIG. 20 is a diagram showing the configuration of a current source device 1Q. The current source device 1Q includes an NMOS transistor 11, a voltage booster 30, a controller 40A and so on.

The drain of the NMOS transistor 11 is connected to the first reference potential supply terminal that supplies the first reference potential (e.g., a power supply potential). The current output from the source of the NMOS transistor 11 is input to the load circuit 3. The voltage booster 30 provides a potential equal to or higher than the reference potential to the gate of the NMOS transistor 11. The controller 40A controls the potential provided by the voltage booster 30 to the gate of the NMOS transistor 11 based on a current or a potential at a predetermined node in the load circuit 3 that receives the current output from the source of the NMOS transistor.

In the configuration example shown in this figure, a current source 42 is provided between the output terminal of the voltage booster 30 and the second reference potential supply terminal (e.g., ground potential supply terminal). The controller 40A controls the current flowing through the current source 42 to adjust the potential provided to the gate of the NMOS transistor 11 so that the current or the potential at a predetermined node in the load circuit 3 becomes a desired value.

The load circuit 3 may be arbitrary and may be a circuit that requires high-speed operation. The current source device 1Q uses the NMOS transistor 11 for current supply and provides a potential equal to or higher than the reference potential to the gate of the NMOS transistor 11, making it easy to achieve high-speed operation and large current amplitude output, and it can suitably supply current to the load circuit 3 that requires high-speed operation.

The above-described devices include elements of the following examples.

(Example 1) The voltage-current conversion device (FIGS. 1 to 17, 19) of Example 1 includes: a current supply circuit (10A to 10J, 10P) including a first NMOS transistor 11 having a drain connected to a first reference potential supply terminal V1; a voltage booster 30 (voltage boosting circuit) having an output terminal connected to a gate of the first NMOS transistor 11; a first resistor (13, 54) provided downstream of the first NMOS transistor 11; an output terminal OUT connected to a first node NI located downstream of the first resistor; a controller 40A configured to control an output potential of the output terminal of the voltage booster 30 based on a potential of the first node N1; and a differential circuit including a first NPN transistor disposed downstream of the first NMOS transistor, and a second NPN transistor disposed downstream of the first reference potential supply terminal, wherein differential input signals are provided to a first base of the first NPN transistor and a second base of the second NPN transistor.

(Example 2) According to the voltage-current conversion device (FIGS. 1 to 17) of Example 2, in the device of Example 1, the current supply circuit includes a second NMOS transistor 12 having a gate connected to the gate of the first NMOS transistor 11 and a drain connected to the first reference potential supply terminal V1, the output terminal of the voltage booster 30 is connected to the gates of the first and second NMOS transistors, and the second NPN transistor 22 of the differential circuit is disposed downstream of the second NMOS transistor 12.

(Example 3) The voltage-current conversion device (FIGS. 1 to 17) of Example 3, in the device of Example 2, further includes a second resistor 14 provided downstream of the second NMOS transistor 12, wherein the first NPN transistor 21 is disposed downstream of the first resistor 13, the second NPN transistor 22 is disposed downstream of the second resistor 14, and the first node N1 is located between the first resistor 13 and the first NPN transistor 21.

(Example 4) According to the voltage-current conversion device (FIGS. 6 to 8) of Example 4, in the device of Example 2, one end of the first resistor 54 is connected to a node between the first NMOS transistor 11 and the first NPN transistor 21, and the other end of the first resistor 54 is connected to the first node N1.

(Example 5) The voltage-current conversion device (FIGS. 2, 3, 7 to 14, 16, 17) of Example 5, in the device of Example 2, further includes: a third resistor 52 provided between the source of the first NMOS transistor 11 and a third node N3; and a current source 53 provided between the third node N3 and the second reference potential supply terminal V2, wherein the controller controls the output potential of the output terminal of the voltage booster 30 based on a comparison between the potential of the first node N1 and the potential of the third node N3.

(Example 6) The voltage-current conversion device (FIG. 3, FIG. 8) of Example 6, in the device of Example 2, further includes: a third NMOS transistor 51 having a drain connected to the first reference potential supply terminal V1 and a gate connected to the gates of the first and second NMOS transistors; a third resistor 52 provided between the source of the third NMOS transistor 51 and the third node N3; and a current source 53 provided between the third node N3 and the second reference potential supply terminal V2, wherein the controller controls the output potential of the output terminal of the voltage booster 30 based on a comparison between the potential of the first node N1 and the potential of the third node N3.

(Example 7) According to the voltage-current conversion device of Example 7, in the device of Example 2, the first NMOS transistor 11 is an N-type lateral double-diffused (LDMOS) metal-oxide-semiconductor (MOS) field-effect transistor, and the second NMOS transistor 12 is an N-type lateral double-diffused (LDMOS) metal-oxide-semiconductor (MOS) field-effect transistor.

(Example 8) According to the voltage-current conversion device (FIG. 9) of Example 8, in the device of Example 2, the first NMOS transistor 11 has a triple-well structure, the second NMOS transistor 12 has a triple-well structure, and a resistor 15 is provided between the P-well of the first NMOS transistor and the P-well of the second NMOS transistor and the first node N1.

(Example 9) According to the voltage-current conversion device (FIG. 10) of Example 9, in the device of Example 2, the first NMOS transistor 11 has a triple-well structure, the second NMOS transistor 12 has a triple-well structure, and a resistor 16 is provided between the P-well of the first NMOS transistor 11 and the P-well of the second NMOS transistor 12 and the source of the first NMOS transistor 11.

(Example 10) According to the voltage-current conversion device (FIG. 11) of Example 10, in the device of Example 2, the first NMOS transistor 11 has a triple-well structure, the second NMOS transistor 12 has a triple-well structure, and a voltage source 17 is provided between the P-well of the first NMOS transistor 11 and the P-well of the second NMOS transistor 12 and the first reference potential supply terminal V1.

(Example 11) According to the voltage-current conversion device (FIG. 12) of Example 11, in the device of Example 2, the first NMOS transistor 11 has a triple-well structure, the second NMOS transistor 12 has a triple-well structure, and diodes (DA, DB) are provided between the P-well of the first NMOS transistor 11 and the P-well of the second NMOS transistor 12 and the first reference potential supply terminal.

(Example 12) According to the voltage-current conversion device (FIGS. 1 to 3, 6 to 12, 14, 16 to 17, 19) of Example 12, in the device of Example 2, the differential circuit 20A includes the first NPN transistor 21 and the second NPN transistor 22, and a tail current source 23 provided between the first NPN transistor 21 and the second NPN transistor 22 and the second reference potential supply terminal V2.

(Example 13) According to the voltage-current conversion device (FIG. 13) of Example 13, in the device of Example 2, the differential circuit 20K includes a first tail current source 25 provided between the first NPN transistor 21 and the second reference potential supply terminal V2, and a second tail current source 26 provided between the second NPN transistor 22 and the second reference potential supply terminal V2.

(Example 14) The voltage-current conversion device (FIG. 14) of Example 14, in the device of Example 3, further includes a dummy load 60 connected to the second node N2 between the second resistor 14 and the second NPN transistor 22.

(Example 15) According to the voltage-current conversion device (FIG. 16) of Example 15, in the device of Example 5, the resistance value of the third resistor 52 or the current value of the current source 53 is variable.

(Example 16) The voltage-current conversion device (FIG. 17) of Example 16, in the device of Example 2, includes a plurality of current supply circuits 10A, wherein the number of current supply circuits 10A connected to the first reference potential supply terminal V1, among the plurality of current supply circuits 10A, is variable.

(Example 17) The voltage-current conversion device (FIG. 18) of Example 17 includes: a current supply circuit (10o) comprising a first upstream NPN transistor 111 having a collector connected to the first reference potential supply terminal V1, a voltage booster 30 having an output terminal connected to the base of the first upstream NPN transistor 111, a first resistor 13 provided downstream of the first upstream NPN transistor 111, an output terminal OUT connected to a first node N1 located downstream of the first resistor, a controller 40A configured to control the output potential of the voltage booster 30 based on the potential of the first node N1, and a differential circuit 20A including a first NPN transistor 21 disposed downstream of the first upstream NPN transistor 111 and a second NPN transistor 22 disposed downstream of the first reference potential supply terminal V1, wherein differential input signals are respectively provided to the first base of the first NPN transistor 21 and the second base of the second NPN transistor 22.

(Example 18) According to the voltage-current conversion device (FIG. 18) of Example 18, in the device of Example 17, the current supply circuit 10o includes a second upstream NPN transistor 112 having a gate connected to the gate of the first upstream NPN transistor 111 and a drain connected to the first reference potential supply terminal V1, the output terminal of the voltage booster 30 is connected to the gates of the first and second upstream NMOS transistors, and the second NPN transistor 22 of the differential circuit 20A is disposed downstream of the second upstream NPN transistor 12.

(Example 19) The voltage-current conversion device (FIG. 18) of Example 19, in the device of Example 18, further includes a second resistor 14 provided downstream of the second upstream NPN transistor 112, wherein the first upstream NPN transistor 111 is disposed downstream of the first resistor 13, the second NPN transistor 22 is disposed downstream of the second resistor 14, and the first node N1 is located between the first resistor 13 and the first NPN transistor 21.

(Example 20) The current source device (FIG. 20) of Example 20 includes a first NMOS transistor 11 having a drain connected to the first reference potential supply terminal V1, a voltage booster 30 configured to provide a potential equal to or higher than the first reference potential to the gate of the first NMOS transistor 11, and a controller 40A configured to control the potential provided by the voltage booster 30 to the gate of the first NMOS transistor 11 based on a current or a potential in a load circuit 3 that receives the current output from the source of the first NMOS transistor 11.

Various modifications to the above-described embodiments will be readily apparent to those skilled in the art, and the principles defined herein may be applied to other embodiments without departing from the scope of the present disclosure. The various features of the described embodiments and examples may be combined. Individual features may be included in different claims, but they may be advantageously combined. The present invention is not limited to the above examples and is defined by the scope of the claims, with the intention that all modifications within the meaning and range equivalent to the claims are included.

### REFERENCE SIGNS LIST

1A to 1P . . . voltage-current conversion device, 1Q . . . current source device, 2 . . . load, 3 . . . load circuit, 10A, 10D, 10G to 10J, 10o, 10P . . . current supply circuit, 11 . . . first NMOS transistor, 12 . . . second NMOS transistor, 13 . . . first resistor, 14 . . . second resistor, 15 . . . fourth resistor, 16 . . . fifth resistor, 17 . . . voltage source, 18 . . . diode, 111, 112 . . . NPN transistor, 20A, 20K . . . differential circuit, 21 . . . first NPN transistor, 22 . . . second NPN transistor, 23 . . . tail current source, 24 . . . resistor, 25, 26 . . . tail current source, 30 . . . voltage booster, 40A . . . controller, 40B . . . controller (current pull-out amplifier), 41 . . . low-pass filter, 42 . . . current source, 51 . . . third NMOS transistor, 52 . . . third resistor, 53 . . . current source, 54 . . . resistor, 60 . . . dummy load, 61 to 63 . . . switch, N1 . . . first node, N2 . . . second node, N3 . . . third node.

1. (canceled)

2. (canceled)

3. The voltage-current conversion device according to claim 19, further comprising:
a third resistor provided between a source of the first NMOS transistor and a third node; and
a current source provided between the third node and a second reference potential supply terminal,
wherein the controller controls the potential provided by the voltage booster to each gate of the first NMOS transistor and the second NMOS transistor, based on a comparison between a current flowing through the first resistor or a potential of the first node, and a current flowing through the third resistor or a potential of the third node.

4. The voltage-current conversion device according to claim 19, further comprising:
a third NMOS transistor having a drain connected to the first reference potential supply terminal;
a third resistor provided between a source of the third NMOS transistor and a third node; and
a current source provided between the third node and the second reference potential supply terminal,
wherein the gates of the first NMOS transistor, the second NMOS transistor, and the third NMOS transistor are mutually connected, and
wherein the controller controls the potential provided by the voltage booster to each gate of the first NMOS transistor, the second NMOS transistor, and the third NMOS transistor based on a comparison between the a current flowing through the first resistor or a potential of the first node and a current flowing through the third resistor or a potential of the third node.

5. The voltage-current conversion device according to claim 18,
wherein the first NMOS transistor and the second NMOS transistor are both N-type LDMOS transistors.

6. The voltage-current conversion device according to claim 18,
wherein the first NMOS transistor and the second NMOS transistor each have a triple-well structure, and a resistor is provided between each P-well of the first and second NMOS transistors and the first node.

7. The voltage-current conversion device according to claim 18,
wherein the first NMOS transistor and the second NMOS transistor each have a triple-well structure, and a resistor is provided between each P-well of the first and second NMOS transistors and the source of the first NMOS transistor.

8. The voltage-current conversion device according to claim 18,
wherein the first NMOS transistor and the second NMOS transistor each have a triple-well structure, and a voltage source is provided between each P-well of the first and second NMOS transistors and the first reference potential supply terminal.

9. The voltage-current conversion device according to claim 18,
wherein the first NMOS transistor and the second NMOS transistor each have a triple-well structure, and a diode is provided between each P-well of the first and second NMOS transistors and the first reference potential supply terminal.

10. The voltage-current conversion device according to claim 17,
wherein the differential circuit includes:
a tail current source provided between the second reference potential supply terminal and an emitter of the first NPN transistor, and
another tail current source provided between the second reference potential supply terminal and an emitter of the second NPN transistor.

11. The voltage-current conversion device according to claim 17, wherein a dummy load is connected to a second node, wherein the second NPN transistor has a collector connected to the second node.

12. The voltage-current conversion device according to claim 3, wherein a resistance value of the third resistor or a current value of the current source is variable.

13. The voltage-current conversion device according to claim 17, comprising a plurality of the current supply circuits, wherein a number of the current supply circuits connected to the first reference potential supply terminal is variable.

14. A voltage-current conversion device, comprising:
a current supply circuit including:
a first NPN transistor and a second NPN transistor, each having their respective collectors connected to a first reference potential supply terminal that supplies a first reference potential;
a first resistor provided between an emitter of the first NPN transistor and a first node; and
a second resistor provided between an emitter of the second NPN transistor and a second node;
wherein bases of the first NPN transistor and the second NPN transistor are connected to each other;
a differential circuit including:
a third NPN transistor having a collector connected to the first node;
a fourth NPN transistor having a collector connected to the second node;
a tail current source provided between a second reference potential supply terminal, which supplies a second reference potential lower than the first reference potential, and emitters of both of the third NPN transistor and the fourth NPN transistor;
a voltage booster configured to provide a potential equal to or higher than the first reference potential to each base of the first NPN transistor and the second NPN transistor; and
a controller configured to control the potential provided by the voltage booster to each base of the first NPN transistor and the second NPN transistor based on a current flowing through the first resistor or a potential of the first node,
wherein differential voltage signals are input to respective bases of the third NPN transistor and the fourth NPN transistor, and a current signal corresponding to these differential voltage signals is output from the first node.

15. (canceled)

16. A current source device, comprising:
an NMOS transistor having a drain connected to a reference potential supply terminal that supplies a reference potential;
a voltage booster configured to provide a potential equal to or higher than the reference potential to a gate of the NMOS transistor; and
a controller configured to control the potential provided by the voltage booster to the gate of the NMOS transistor based on a current or a potential in a load circuit that receives a current output from a source of the NMOS transistor.

17. A voltage-current conversion device, comprising:
a current supply circuit including a first NMOS transistor having a drain connected to a first reference potential supply terminal;
a voltage booster having an output terminal connected to a gate of the first NMOS transistor;
a first resistor provided downstream of the first NMOS transistor;
an output terminal connected to a first node located downstream of the first resistor;
a controller configured to control an output potential of the voltage booster based on a potential of the first node; and
a differential circuit including a first NPN transistor disposed downstream of the first NMOS transistor, and a second NPN transistor disposed downstream of the first reference potential supply terminal,
wherein differential input signals are respectively provided to a first base of the first NPN transistor and a second base of the second NPN transistor.

18. The voltage-current conversion device according to claim 17,
wherein the current supply circuit includes a second NMOS transistor having:
a gate connected to the gate of the first NMOS transistor, and
a drain connected to the first reference potential supply terminal;
wherein the output terminal of the voltage booster is connected to the gates of the first and second NMOS transistors, and
wherein the second NPN transistor of the differential circuit is disposed downstream of the second NMOS transistor.

19. The voltage-current conversion device according to claim 18, further comprising a second resistor provided downstream of the second NMOS transistor,
wherein the first NPN transistor is disposed downstream of the first resistor;
wherein the second NPN transistor is disposed downstream of the second resistor; and
wherein the first node is located between the first resistor and the first NPN transistor.

20. The voltage-current conversion device according to claim 18,
wherein one end of the first resistor is connected to a node between the first NMOS transistor and the first NPN transistor, and another end of the first resistor is connected to the first node.

21. The voltage-current conversion device according to claim 19, further comprising:
a third resistor provided between a source of the first NMOS transistor and a third node; and
a current source provided between the third node and a second reference potential supply terminal,
wherein the controller controls the output potential of the output terminal of the voltage booster based on a comparison between a potential of the first node and a potential of the third node.

22. The voltage-current conversion device according to claim 17, wherein the current supply circuit includes the first resistor.
